(19) United States
(12) Patent Application Publication
(10) Pub. No.: US 2019/0322809 A1
(43) Pub. Date: Oct. 24, 2019

(54) LIQUID OPTICAL SILICONE COMPOSITION, OPTICAL SILICONE, DOUBLE-GLASS PHOTOVOLTAIC ASSEMBLY, AND PREPARATION METHOD THEREFOR

(71) Applicant: BYD COMPANY LIMITED, SHENZHEN, GUANGDONG (CN)

(72) Inventors: Shouping BAI, Shenzhen (CN); Wei ZHOU, Shenzhen (CN); Xiaokang DAI, Shenzhen (CN); Zhenwei LI, Shenzhen (CN); Tingting HU, Shenzhen (CN)

(73) Assignee: BYD COMPANY LIMITED, SHENZHEN, GUANGDONG (CN)

(21) Appl. No.: 16/475,028

(22) PCT Filed: Dec. 8, 2017
(86) PCT No.: PCT/CN2017/115138

§ 371 Date: Jun. 28, 2019

(30) Foreign Application Priority Data
Dec. 29, 2016 (CN) 201611243886.8

(51) Int. Cl. C08G 77/20; C08G 77/12; C08G 77/00; C08G 77/08; C08L 83/10; H01L 31/048

(52) U.S. Cl. CPC C08G 77/20; C08G 77/12; H01L 31/0488; C08G 77/08; C08L 83/10; C08G 77/70

(57) ABSTRACT

The present disclosure relates to the field of silica gel, and discloses a liquid optical silica gel composition, optical silica gel, a double-glazed photovoltaic assembly and a fabrication method of the optical silica gel. The present disclosure discloses a liquid optical silica gel composition. The composition contains vinyl silicone oil, hydrogen-containing silicone oil, hydrogen-containing MQ silicone resin, a catalyst, an inhibitor and a tackifier. The weight ratio between the vinyl silicone oil, the hydrogen-containing silicone oil, the hydrogen-containing MQ silicone resin and the tackifier is 1:(0.001-0.1):(0.0001-0.08):(0.001-0.05). The hydrogen-containing silicone oil contains first hydrogen-containing silicone oil and second hydrogen-containing silicone oil. The first hydrogen-containing silicone oil has a hydrogen content of 0.1 to 1 percent by weight. The second hydrogen-containing silicone oil has a hydrogen content of 0.01 to 0.1 percent by weight. The hydrogen-containing MQ silicone resin has a hydrogen content less than 1 percent by weight.

### CROSS-REFERENCE TO RELATED APPLICATIONS

This application claims priority to and benefits of Chinese Patent Application No. 201611243886.8, filed with the State Intellectual Property Office of P. R. China on Dec. 29, 2016. The entire content of the above-referenced application is incorporated herein by reference.

### FIELD

The present disclosure relates to the field of silicone or silica gel, and more particularly relates to a liquid optical silica gel composition, optical silica gel, a double-glazed photovoltaic assembly and a fabrication method of the optical silica gel.

### BACKGROUND

A solar cell can convert solar energy into electrical energy by using its photovoltaic effect. It has the advantages of environmental protection and inexhaustibility, and is an important development that may replace conventional oil and gas energy. The solar cells are generally divided into crystalline silicon solar cells, thin film solar cells, dye-sensitized solar cells, and organic solar cells. After years of research and development and marketing, currently, the crystalline silicon solar cells have gradually dominated in the field of solar cells.

Generally, a fabrication method of the crystalline silicon solar cell includes sequentially stacking a glass sheet, a transparent EVA (ethylene vinyl acetate) adhesive film, a cell piece, an EVA adhesive film, and a back plate together and formed by hot press.

Compared with the EVA adhesive film, a liquid silica gel material is better in weather resistance, especially ultraviolet resistance, so this material has new development and application in the photovoltaic field.

However, it has been found that a conventional silica gel composition has a low curing speed and low strength during fabrication of a double-glazed assembly. However, increasing the curing speed and enhancing the strength may cause side effects under wet and hot conditions, resulting in an abnormal assembly. Therefore, there is an urgent need to research and develop a silica gel composition which has high curing speed, high strength, and high hydrothermal stability.

### SUMMARY

The present disclosure aims to overcome the problems in the prior art that a silica gel composition may have side effects under wet and hot conditions and low curing speed. The present disclosure provides a liquid optical silica gel composition, an optical silica gel, a double-glazed photovoltaic assembly, and a fabrication method of the optical silica gel.

In order to achieve the foregoing objective, the present disclosure provides a liquid optical silica gel composition. The composition comprises a vinyl silicone oil, a hydrogen-containing silicone oil, a hydrogen-containing MQ (Me₃SiO+SiO₄) silicone resin, a catalyst, an inhibitor, and a tackifier. The weight ratio between the vinyl silicone oil, the hydrogen-containing silicone oil, the hydrogen-containing MQ silicone resin, and the tackifier is 1:(0.001-0.1):(0.0001-0.08):(0.001-0.05). The hydrogen-containing silicone oil comprises a first hydrogen-containing silicone oil and second hydrogen-containing silicone oil. The first hydrogen-containing silicone oil has a hydrogen content of 0.1 to 1 percent by weight. The second hydrogen-containing silicone oil has a hydrogen content of 0.01 to 0.1 percent by weight. The hydrogen-containing MQ silicone resin has a hydrogen content less than 1 percent by weight.

In a second aspect, the present disclosure provides a method for preparing an optical silica gel. The method includes mixing various components of a liquid optical silica gel composition, and then curing the mixture, wherein the liquid optical silica gel composition is the foregoing composition.

In a third aspect, the present disclosure provides the optical silica gel fabricated by the above method.

In a fourth aspect, the present disclosure provides a double-glazed photovoltaic assembly. The double-glazed photovoltaic assembly includes the above optical silica gel.

The present disclosure provides the liquid optical silica gel composition which may be cured fast and also maintain the stability under wet and hot conditions. The curing time of the liquid optical silica gel composition may be as short as 6 to 23 minutes. Furthermore, the optical silica gel fabricated from the liquid optical silica gel composition of the present disclosure can be used to fabricate the double-glazed photovoltaic assembly.

Other features and advantages of the present disclosure are described in detail in the following specific implementations.

### DETAILED DESCRIPTION

Embodiments of the present disclosure are described in detail below. It should be understood that the embodiments described herein are merely used to describe and explain this disclosure rather than limit this disclosure.

Endpoints of all ranges and all values disclosed herein are not limited to the precise ranges or values, and these ranges or values should be understood as including values close to these ranges or values. For value ranges, endpoint values of the different ranges, the endpoint values and individual point values of the ranges, and the individual point values can be combined with each other to obtain one or more new value ranges. All these value ranges should be considered as being specifically disclosed in this specification.

The present disclosure provides a liquid optical silica gel composition. The composition contains vinyl silicone oil, hydrogen-containing silicone oil, hydrogen-containing MQ silicone resin, a catalyst, an inhibitor, and a tackifier. The weight ratio among the vinyl silicone oil, the hydrogen-containing silicone oil, the hydrogen-containing MQ silicone resin, and the tackifier is 1:(0.001-0.1):(0.0001-0.08):(0.001-0.05). The hydrogen-containing silicone oil contains a first hydrogen-containing silicone oil and a second hydrogen-containing silicone oil. The first hydrogen-containing silicone oil has a hydrogen content of 0.1 to 1 percent by weight (wt %). The second hydrogen-containing silicone oil has a hydrogen content of 0.01 to 0.1 wt %. The hydrogen-containing MQ silicone resin has a hydrogen content less than 1 wt %.

According to some embodiments of the present disclosure, the weight ratio among the vinyl silicone oil, the hydrogen-containing silicone oil, the hydrogen-containing MQ silicone resin, and the tackifier is 1:(0.005-0.05):(0.0001-0.05):(0.001-0.02), thereby significantly increasing the curing speed of the composition and improving the stability of the composition under the wet and hot conditions.

In the embodiments of the present disclosure, the hydrogen-containing MQ silicone resin is defined as MQ silicone resin containing a hydrosilation reactive group, which is fabricated by adding tetramethoxydisiloxane in a reaction system. A fabrication method of the hydrogen-containing MQ silicone resin may include various conventional methods in the art. For example, the fabrication method of the hydrogen-containing MQ silicone resin may include a reflux reaction of 400 to 600 parts by weight of tetraethyl orthosilicate, 200 to 300 parts by weight of hexamethyldisiloxane, 100 to 200 parts by weight of tetramethyldisiloxane, 50 to 100 parts by weight of hydrochloric acid, 30 to 70 parts by weight of ethanol, and 80 to 150 parts by weight of water at 50 to 90° C. for 2 to 5 hours. After the reflux reaction is completed, the ethanol in the product is distilled off. After the product is cooled to room temperature, 400 to 600 parts by weight of toluene is added for extraction, an aqueous phase is removed, and an organic phase is washed with deionized water until neutral. Then a pressure distillation is performed at 60 to 100° C. and −0.1 to −0.07 MPa to obtain a hydrogen-containing MQ resin.

In the present disclosure, the hydrogen content of the first hydrogen-containing silicone oil is greater than that of the second hydrogen-containing silicone oil.

According to the composition of the present disclosure, the hydrogen content of the hydrogen-containing MQ silicone resin may be less than 0.5 wt %, but its minimum value should be more than 0.

According to the composition of the present disclosure, a ratio of a total hydrogen content of the second hydrogen-containing silicone oil and the hydrogen-containing MQ silicone resin to the hydrogen content of the first hydrogen-containing silicone oil is 1:(1 to 99). According to some embodiments of this disclosure, a ratio of a total hydrogen content of the second hydrogen-containing silicone oil and the hydrogen-containing MQ silicone resin to the hydrogen content of the first hydrogen-containing silicone oil is 1:(1 to 80). According to some embodiments of this disclosure, a ratio of a total hydrogen content of the second hydrogen-containing silicone oil and the hydrogen-containing MQ silicone resin to the hydrogen content of the first hydrogen-containing silicone oil is 1:(1 to 70). According to some embodiments of this disclosure, a ratio of a total hydrogen content of the second hydrogen-containing silicone oil and the hydrogen-containing MQ silicone resin to the hydrogen content of the first hydrogen-containing silicone oil is 1:(1 to 60). According to some embodiments of this disclosure, a ratio of a total hydrogen content of the second hydrogen-containing silicone oil and the hydrogen-containing MQ silicone resin to the hydrogen content of the first hydrogen-containing silicone oil is 1:(1 to 50). Therefore, the curing speed of the composition can be significantly increased and the stability of the composition under the wet and hot conditions can be improved. In an embodiment of the present disclosure, the ratio of the total hydrogen content of the second hydrogen-containing silicone oil and the hydrogen-containing MQ silicone resin to the hydrogen content of the first hydrogen-containing silicone oil is any values of 1:(1 to 40), 1:(1 to 30), 1:(1 to 20), or 1:(1 to 10).

According to the composition of the present disclosure, a ratio of the total hydrogen content of the composition to the vinyl content may be (0.9 to 2.5): 1. According to some embodiments of this disclosure, a ratio of the total hydrogen content of the composition to the vinyl content may be (1.2 to 1.8):1. Therefore, the curing speed of the composition can be significantly increased, and the stability of the composition under the wet and hot conditions can be improved.

According to the composition of the present disclosure, the tackifier may be various conventional tackifiers in the art, for example, a vinyl-containing silane coupling agent and/or a siloxane oligomer. The silane coupling agent of the present disclosure may be at least one of gamma-(methylacryloyloxy) propyltrimethoxysilane (KH570), vinyltriethoxysilane, and vinyltrimethoxysilane.

The tackifiers of the present disclosure may contain a vinyl group. According to the composition of the present disclosure, the vinyl content ratio of the vinyl silicone oil to the tackifier may be (2 to 3):1, so that the viscosity of the composition may be effectively controlled, thereby further increasing the curing speed of the composition.

According to the composition of the present disclosure, the catalyst may include a platinum-series catalyst capable of catalyzing reaction of the vinyl silicone oil with the hydrogen-containing silicone oil and the hydrogen-containing MQ silicone resin, for example, a chloroplatinic acid/olefin complex and a chloroplatinic acid/divinyl tetramethyldisiloxane complex. In embodiments of the present disclosure, the content of pt (platinum) in the final composition may be controlled to be 2 to 20 ppm.

According to the composition of the present disclosure, the inhibitor may be various inhibitors in the art, for example, at least one of alkynol and tetramethyl tetravinylcyclotetrasiloxane (V4). In embodiments of the present disclosure, the inhibitor may be 0.0001 to 0.1 wt % based on the total weight of the liquid optical silica gel composition.

According to the composition of the present disclosure, the vinyl silicone oil may be composed of two types of vinyl silicone oil with different viscosities, for example, formed by mixing high-viscosity vinyl silicone oil (having the viscosity of 100,000 to 150,000 cps) with low-viscosity vinyl silicone oil (having the viscosity of 4,000 to 5,000 cps) according to a weight ratio of (6 to 10):1.

In an implementation of the present disclosure, no inorganic filler in the composition of the present disclosure and the use of the MQ resin as a reinforcing material may significantly increase the curing speed of the composition, improve the stability of the composition under the wet and hot conditions, and maintain a high transparency. A conventional inorganic filler may be, for example, white carbon black, alumina, or the like. If the composition contains a filler, the optical properties of the liquid optical silica gel composition will be affected, resulting in a poor light transmittance of the optical silica gel.

The liquid optical silica gel composition of the present disclosure may be stored in groups, as long as the vinyl silicone oil does not react with the hydrogen-containing silicone oil and the hydrogen-containing MQ silicone resin during the storage. For example, the liquid optical silica gel composition may include component A and component B, wherein the component A may contain the catalyst and the tackifier, and the component B may contain the hydrogen-containing silicone oil, the hydrogen-containing MQ silicone resin, and the inhibitor. Each of the component A and component B may contain the vinyl silicone oil. The content of the vinyl silicone oil in the component A and component B may be equal or unequal according to actual needs, to finally ensure that the component A and component B are mixed in a certain ratio to reach the weight ratios of the various components in the liquid optical silica gel composition of the present disclosure.

In a second aspect, the present disclosure provides a method for g fabricating the optical silica gel. The method includes mixing various components of a liquid optical silica gel composition and curing the mixture, wherein the liquid optical silica gel composition is the composition disclosed above.

According to the method of the present disclosure described above, the liquid optical silica gel composition may be stored in groups, and then the various components of the liquid optical silica gel composition are mixed and then cured before use. The curing condition may include a temperature of 60 to 75° C. The liquid optical silica gel composition of the present disclosure may be cured fast at the temperature of 60 to 75° C., and the curing time may be as short as 6 to 23 minutes.

In a third aspect, the present disclosure provides optical silica gel fabricated by the method disclosed above.

In a fourth aspect, the present disclosure provides a double-glazed photovoltaic assembly, and the double-glazed photovoltaic assembly includes the optical silica gel disclosed above.

The structure of the double-glazed photovoltaic assembly of the present disclosure may include a front side glass, a first optical silica gel, a solar cell piece, a second optical silica gel, and a back side glass, which are sequentially laminated. The assembly may be formed by vacuuming and lamination curing by a laminating machine at 60 to 75° C. At least one of the first optical silica gel and the second optical silica gel is the optical silica gel described above in the present disclosure.

The embodiments of the present disclosure are described in detail below.

The fabrication method of the hydrogen-containing MQ silicone resin B043 includes a reflux reaction performed on 500 parts by weight of tetraethyl orthosilicate, 250 parts by weight of hexamethyldisiloxane, 150 parts by weight of tetramethyldisiloxane, 70 parts by weight of hydrochloric acid, 50 parts by weight of ethanol, and 120 parts by weight of water at 75° C. for 3 hours. After the reaction was completed, the ethanol in the system was distilled off. The product was cooled to room temperature. 500 parts by weight of toluene was added for extraction, an aqueous phase was removed, and an organic phase was washed with deionized water until neutral. And then pressure distillation was performed at 80° C. and −0.09 MPa to obtain the hydrogen-containing MQ resin B043.

### Embodiments 1 to 7

The embodiment of the present disclosure is used for describing the liquid optical silica gel composition of the present disclosure.

The liquid optical silica gel composition includes component A and component B for storage. The component A comprises the vinyl silicone oil, the catalyst, and the tackifier. The component B comprises the vinyl silicone oil, the hydrogen-containing silicone oil, the hydrogen-containing MQ silicone resin, and the inhibitor. The property descriptions of the various components in the liquid optical silica gel composition are shown in Table 1 below, the specific compositions are shown in Table 2 below, and ratios of the various components are shown in Table 3 below.

### Comparison Example 1

The liquid optical silica gel composition includes component A and component B for storage. The component A comprises the vinyl silicone oil, the catalyst, and the tackifier. The component B comprises the vinyl silicone oil, the hydrogen-containing silicone oil, the hydrogen-containing MQ silicone resin, and the inhibitor. The property descriptions of the various components in the liquid optical silica gel composition are shown in Table 1 below, the specific compositions are shown in Table 2 below, and ratios of the various components are shown in Table 3 below.

TABLE 1

| | | | Hydrogen | |
|---|---|---|---|---|
| | Vinyl content | Viscosity | content | |
| Product | (mmol/g) | (cps) | (%) | Manufacturer |
| High-viscosity vinyl | 0.02 | 100000 | / | AB SPECIALTY |
| silicone oil VS100000 | | | | SILICONES CO., LTD |
| Low-viscosity vinyl | 0.07 | 4000 | / | AB SPECIALTY |
| silicone oil VS4000 | | | | SILICONES CO., LTD |
| Silane coupling agent | 4.3 | / | / | DOW Corning |
| KH570 | | | | |
| First hydrogen-containing | / | / | 0.755 | AB SPECIALTY |
| silicone oil XL10 | | | | SILICONES CO., LTD |
| Second | / | / | 0.02 | AB SPECIALTY |
| hydrogen-containing | | | | SILICONES CO., LTD |
| silicone oil XL-17 | | | | |
| Hydrogen-containing MQ | / | / | 0.43 | Self-synthesized |
| silicone resin B043 | | | | |
| Platinum-series catalyst | | | | Shanghai Vivo |
| Heraeus Karstedt | | | | Chemical Co., LTD |
| Tetramethyl | | | | J&K Scientific Ltd. |
| tetravinylcyclotetrasiloxane | | | | |
| (V4) | | | | |

TABLE 2

| | | | | First hydrogen- | Second hydrogen- | Hydrogen- | | | |
|---|---|---|---|---|---|---|---|---|---|
| | | | | containing | containing | containing | Tackifier | | |
| | | Vinyl silicone oil | | silicone oil | silicone oil | MQ silicone resin | (parts | Catalyst | |
| | | (parts by weight) | | (parts by weight) | (parts by weight) | (parts by weight) | by weight) | Heraeus | Inhibitor |
| | Component Name | VS1000000 | VS4000 | XL10 | XL-17 | B043 | KH570 | Karstedt | V4 |
| Embodiment 1 | Component A | 150 | 25 | / | / | / | 1.2 | 4 ppm | / |
| | Component B | 150 | 25 | 1.5 | 2.5 | 1 | / | / | 0.04 |
| Embodiment 2 | Component A | 150 | 25 | / | / | / | 1.2 | 4 ppm | / |
| | Component B | 150 | 25 | 3 | 0.5 | 0.4 | / | / | 0.04 |
| Embodiment 3 | Component A | 150 | 25 | / | / | / | 1.2 | 4 ppm | / |
| | Component B | 150 | 25 | 2.5 | 0.1 | 0.1 | / | / | 0.04 |
| Embodiment 4 | Component A | 150 | 25 | / | / | / | 1.2 | 4 ppm | / |
| | Component B | 150 | 25 | 3.3 | 0.1 | 0.1 | | | 0.04 |
| Embodiment 5 | Component A | 150 | 25 | / | / | / | 1.2 | 4 ppm | / |
| | Component B | 150 | 25 | 3.3 | 0.05 | 0.05 | | | 0.04 |
| Embodiment 6 | Component A | 150 | 25 | / | / | / | 1.2 | 4 ppm | / |
| | Component B | 150 | 25 | 0.75 | 1.2 | 0.5 | | | 0.04 |
| Embodiment 7 | Component A | 150 | 25 | / | / | / | 1.2 | 4 ppm | |
| | Component B | 150 | 25 | 4.2 | 7 | 2.8 | | | 0.04 |
| Comparison | Component A | 150 | 25 | / | / | / | 1.2 | 4 ppm | / |
| example 1 | Component B | 150 | 25 | 3 | / | / | / | / | 0.04 |

TABLE 3

| | | Ratio of total hydrogen content of | |
|---|---|---|---|
| | Vinyl content | second hydrogen-containing silicone | Ratio of total |
| | ratio of vinyl | oil and hydrogen-containing MQ | hydrogen content |
| | silicone oil to | silicon resin to hydrogen content of | of composition to |
| Number | tackifier | first hydrogen-containing silicone oil | vinyl content |
| Embodiment 1 | 2:1 | 1:2.4 | 1.1:1 |
| Embodiment 2 | 2:1 | 1:12.4 | 1.7:1 |
| Embodiment 3 | 2:1 | 1:42 | 1.3:1 |
| Embodiment 4 | 2:1 | 1:55 | 1.7:1 |
| Embodiment 5 | 2:1 | 1:110 | 1.7:1 |
| Embodiment 6 | 2:1 | 1:2.4 | 0.5:1 |
| Embodiment 7 | 2:1 | 1:2.4 | 3:1 |
| Comparison | 2:1 | / | 1.6:1 |
| example 1 | | | |

### Application Examples

The application examples of the present disclosure are used for describing the optical silica gel, the double-glazed photovoltaic assembly, and a fabrication method of the optical silica gel of the present disclosure.

The component A and the component B were mixed according to the constituents of the liquid optical silica gel composition in Tables 1 to 3 above. Then the mixture was cured at 60° C., and the curing time was recorded (results are shown in Table 4 below) to obtain the optical silica gel A1 to A7 and D1. The obtained optical silica gel was used to fabricate the double-glazed photovoltaic assembly. A fabrication method of the double-glazed photovoltaic assembly includes vacuuming and lamination curing a front side glass, an optical silica gel (A1-A7), a solar cell piece, an optical silica gel (A1-A7), and back side glass by a laminating machine at 60 to 75° C. to form the double-glazed photovoltaic assembly.

TABLE 4

| Number | Curing time (min) |
|---|---|
| Embodiment 1 | 13 |
| Embodiment 2 | 9 |
| Embodiment 3 | 11 |
| Embodiment 4 | 13 |
| Embodiment 5 | 23 |
| Embodiment 6 | 22 |
| Embodiment 7 | 6 |
| Comparison example 1 | 25 |

Test Case 1

Thermostability test: The optical silica gel A1 to A7 and D1 were undergone a weightlessness test at a constant temperature of 85° C. by DSC (Dynamic Stability Control) equipment. Weight changes after 1 hour were recorded as shown in Table 5.

TABLE 5

| Number | Lost weight (%) |
|---|---|
| Embodiment 1 | 2.5 |
| Embodiment 2 | 1.8 |
| Embodiment 3 | 2.8 |
| Embodiment 4 | 2.3 |
| Embodiment 5 | 2.4 |
| Embodiment 6 | 2.3 |
| Embodiment 7 | 2.6 |
| Comparison example 1 | 3.2 |

Test Case 2

The mixture obtained by mixing the component A with the component B in Table 1 to 3 was applied between two layers of glass before it was cured. The peripheries of the glass were sealed with a soft adhesive tape. The product was cured at 60° C., and then placed at 85° C. and humidity of 85 percent for 96 hours to observe whether the condition of the adhesive tape sealed at the edges of the glass was degraded, that is, whether the adhesive tape would be broken or not. If the adhesive tape was broken, this situation was recorded as abnormal. If the adhesive tape was not broken, this situation was recorded as OK. Results are shown in Table 6 below.

TABLE 6

| Number | State |
|---|---|
| Embodiment 1 | OK |
| Embodiment 2 | OK |
| Embodiment 3 | OK |
| Embodiment 4 | OK |
| Embodiment 5 | OK |
| Embodiment 6 | OK |
| Embodiment 7 | OK |
| Comparison example 1 | OK |

The embodiments of the present disclosure provide the liquid optical silica gel composition that may be cured fast and also maintain its stability under the wet and hot conditions. The curing time of the liquid optical silica gel composition may be as short as 6 to 23 minutes. Furthermore, the optical silica gel formed from the liquid optical silica gel composition of the present disclosure can be used to fabricate the double-glazed photovoltaic assembly.

The implementations of the present disclosure are described in detail above. However, the disclosure is not limited to specific embodiments and details in the above implementations. Within the scope of the technical idea of the present disclosure, variances of the technical solutions of the present disclosure may be conducted, and those variances shall all fall within the protection scope of the present disclosure.

It should be further noticed that the specific technical features described in the foregoing specific implementations can be combined in any appropriate manners that have no conflictions. To avoid unnecessary repetition, various possible combination manners will not be described in the present disclosure.

In addition, various implementations of the present disclosure may be combined. Such combinations should also be considered as the content disclosed in the present disclosure as long as the combinations do not depart from the principles of the present disclosure.

1. A liquid optical silica gel composition, comprising:
a vinyl silicone oil, a hydrogen-containing silicone oil, a hydrogen-containing MQ silicone resin, a catalyst, an inhibitor, and a tackifier, wherein
a weight ratio between the vinyl silicone oil, the hydrogen-containing silicone oil, the hydrogen-containing MQ silicone resin, and the tackifier is 1:(0.001-0.1):(0.0001-0.08):(0.001-0.05),
the hydrogen-containing silicone oil contains a first hydrogen-containing silicone oil and a second hydrogen-containing silicone oil,
the first hydrogen-containing silicone oil has a hydrogen content of 0.1 to 1 percent by weight, the second hydrogen-containing silicone oil has a hydrogen content of 0.01 to 0.1 percent by weight, and
the hydrogen-containing MQ silicone resin has a hydrogen content less than 1 percent by weight.

2. The composition according to claim 1, wherein a ratio of a total hydrogen content of the second hydrogen-containing silicone oil and the hydrogen-containing MQ silicone resin to the hydrogen content of the first hydrogen-containing silicone oil is 1:(1 to 99).

3. The composition according to claim 1, wherein a ratio of the total hydrogen content of the composition to the vinyl content is (0.9 to 2.5):1.

4. The composition according to claim 3, wherein the ratio of the total hydrogen content of the composition to the vinyl content is (1.2 to 1.8):1.

5. The composition according to claim 1, wherein the weight ratio among the vinyl silicone oil, the hydrogen-containing silicone oil, the hydrogen-containing MQ silicone resin, and the tackifier is 1:(0.005 to 0.05):(0.0001 to 0.05):(0.001 to 0.02).

6. The composition according to claim 1, wherein the tackifier comprises at least one of a vinyl-containing silane coupling agent and a siloxane oligomer.

7. The composition according to claim 6, wherein the vinyl content ratio of the vinyl silicone oil to the tackifier is (2 to 3):1.

8. The composition according to claim 1, wherein the catalyst comprises a platinum-series catalyst.

9. The composition according to claim 8, wherein the catalyst comprises at least one of a chloroplatinic acid/olefin complex and a chloroplatinic acid/divinyl tetramethyldisiloxane complex.

10. The composition according to claim 1, wherein the composition does not contain inorganic filler.

11. A method for preparing an optical silica gel, comprising:
mixing various components of a liquid optical silica gel composition to form a mixture, wherein the liquid optical silica gel composition includes the composition according to claim 1; and
curing the mixture.

12. The method according to claim 11, further comprising curing the mixture at a temperature of 60 to 75° C.

13. (canceled)

14. A double-glazed photovoltaic assembly, comprising the liquid optical silica gel according to claim 1.

15. The composition according to claim 2, wherein a ratio of a total hydrogen content of the second hydrogen-containing silicone oil and the hydrogen-containing MQ silicone resin to the hydrogen content of the first hydrogen-containing silicone oil is 1:(1 to 80).

16. The composition according to claim 2, wherein a ratio of a total hydrogen content of the second hydrogen-containing silicone oil and the hydrogen-containing MQ silicone resin to the hydrogen content of the first hydrogen-containing silicone oil is 1:(1 to 70).

17. The composition according to claim 2, wherein a ratio of a total hydrogen content of the second hydrogen-containing silicone oil and the hydrogen-containing MQ silicone resin to the hydrogen content of the first hydrogen-containing silicone oil is 1:(1 to 60).

18. The composition according to claim 2, wherein a ratio of a total hydrogen content of the second hydrogen-containing silicone oil and the hydrogen-containing MQ silicone resin to the hydrogen content of the first hydrogen-containing silicone oil is 1:(1 to 50).
